(19) United States
(12) Patent Application Publication
(10) Pub. No.: US 2026/0024578 A1
(43) Pub. Date: Jan. 22, 2026

(54) SEMICONDUCTOR DEVICE AND METHOD OF MANUFACTURING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/779,978

(22) Filed: Jul. 22, 2024

(51) Int. Cl. G11C 11/419; G11C 11/412; H10B 10/00

(52) U.S. Cl. CPC G11C 11/419; G11C 11/412; H10B 10/12

(57) ABSTRACT

A semiconductor device is provided. The semiconductor device comprises a bit cell comprising first and second inverters and a first transistor. The first inverter comprising a second transistor and a third transistor that share a first gate structure extending along a first direction. The second transistor is coupled to a first metal line in a backside of the semiconductor device to receive a first supply voltage. The second inverter is cross-coupled with the first inverter and comprises a fourth transistor and a fifth transistor that share a second gate structure extending along the first direction. The first transistor and second transistors share a first active area extending along a second direction. The first transistor receives first data from a first bit line in a front side of the semiconductor device.

### BACKGROUND

The integrated circuit can typically include individual devices formed in a device layer, such as transistors, capacitors, and the like. One or more layers of metal are then formed on the individual devices to provide connections between individual devices and to external devices. Front-end-of-line (FEOL) is the first part of making an integrated circuit in which individual devices are formed on a wafer. The front-end process usually covers all steps before (but not including) the deposition of the metal layers. The back-end-of-line (BEOL) is the second part of the integrated circuit in which individual devices are connected by wires or metal layers. The back-end process typically begins by depositing a first metal layer on the device layer. To optimize layout of the integrated circuit, individual devices may be connected by metal layers in a backside of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, in accordance with some embodiments of the present disclosure.

FIG. 2 is a schematic diagram of an example of a bit cell corresponding to the memory device in FIG. 1, in accordance with some embodiments of the present disclosure.

FIG. 3 is a schematic diagram of layers of the memory device corresponding to FIGS. 1-2, in accordance with some embodiments of the present disclosure.

FIG. 4A is a layout diagram corresponding to front side of a bit cell configured with respect to the bit cell of memory device of FIGS. 1-3, in accordance with some embodiments of the present disclosure.

FIG. 4B is a layout diagram corresponding to backside of the bit cell of FIG. 4A, in accordance with some embodiments of the present disclosure.

FIGS. 5A-5G are schematic diagrams corresponding to cross-section views along the lines of the bit cell of FIGS. 4A-4B, in accordance with some embodiments of the present disclosure.

FIG. 6A is a layout diagram corresponding to front side of a bit cell configured with respect to the bit cell of FIGS. 4A-4B, 5A-5G and the bit cell of FIGS. 1-3, in accordance with some embodiments of the present disclosure.

FIG. 6B is a layout diagram corresponding to backside of the bit cell of FIG. 6A, in accordance with some embodiments of the present disclosure.

FIG. 7A is a layout diagram corresponding to front side of a bit cell configured with respect to the bit cell of FIGS. 4A-4B, 5A-5G and the bit cell of FIGS. 1-3, in accordance with some embodiments of the present disclosure.

FIG. 7B is a layout diagram corresponding to backside of the bit cell of FIG. 7A, in accordance with some embodiments of the present disclosure.

FIG. 8A is a layout diagram corresponding to front side of a bit cell configured with respect to the bit cell of FIGS. 4A-4B, 5A-5G and the bit cell of FIGS. 1-3, in accordance with some embodiments of the present disclosure.

FIG. 8B is a layout diagram corresponding to backside of the bit cell of FIG. 8A, in accordance with some embodiments of the present disclosure.

FIG. 9A is a layout diagram corresponding to front side of a bit cell configured with respect to the bit cell of the FIGS. 8A-8B, the bit cell of FIGS. 4A-4B, 5A-5G and the bit cell of FIGS. 1-3, in accordance with some embodiments of the present disclosure.

FIG. 9B is a layout diagram corresponding to backside of the bit cell of FIG. 9B, in accordance with some embodiments of the present disclosure.

FIG. 10 is a flowchart diagram of a method for manufacturing the memory device, bit cells as shown in FIGS. 1-3, 4A-4B, 5A-5G, 6A-6B, 7A-7B, 8A-8B, 9A-9B, in accordance with some embodiments of the present disclosure.

FIG. 11 is a block diagram of an electronic design automation (EDA) system for designing the integrated circuit layout design, in accordance with some embodiments of the present disclosure.

FIG. 12 is a block diagram of IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term mask, photolithographic mask, photomask and reticle are used to refer to the same item.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

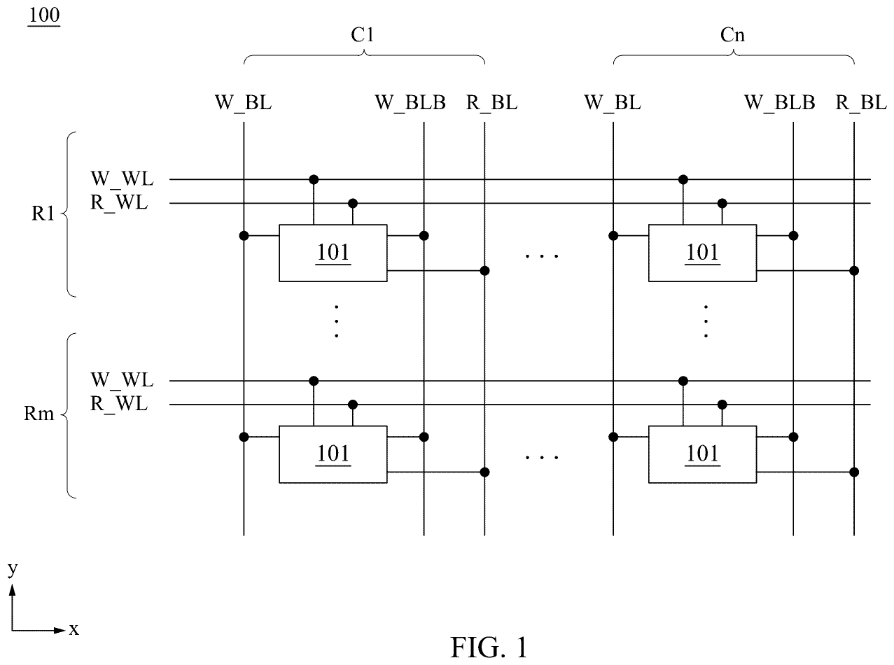

Reference is now made to FIG. 1. FIG. 1 is a schematic diagram of a memory device 100, in accordance with some embodiments of the present disclosure. For illustration, the memory device 100 includes a memory array of bit cells 101. The bit cells 101 are arranged in rows R1-Rm and columns C1-Cn. In some embodiments, the bit cells 101 are static random access memory (SRAM) cells. In some embodiments, the bit cell 101 is a two-port SRAM cell having a write port for write operation and a read port for read operation.

As shown in FIG. 1, the memory device 100 further includes write word lines W_WL, write bit lines W_BL, and write bit lines W_BLB, read word lines R_WL and read bit lines R_BL.

In some embodiments, the write word lines W_WL and the read word lines R_WL extend along a direction x. The write bit lines W_BL, W_BLB and the read bit lines R_BL extend along a direction y. The direction x is perpendicular to the direction y.

The bit cells 101 in a same row are coupled to a corresponding write word line W_WL and a corresponding read word line R_WL. The bit cells 101 in a same column are coupled to a corresponding write bit line W_BL, a corresponding write bit line W_BLB and a corresponding read bit line R_BL.

In practice, the write word line W_WL is configured to transmit a write word line signal to activate the corresponding row of bit cells 101 in a write operation. The write bit lines W_BL and W_BLB coupled to the same column of bit cells 101 are complementary bit lines. In the write operation, the write bit lines W_BL and W_BLB are configured to transmit write data to the activated bit cells 101.

Similarly, the read word line R_WL is configured to transmit a read word line signal to activate the corresponding row of bit cells 101 in a read operation. The read bit line R_BL is configured to receive read data from the activated bit cell 101 in the read operation.

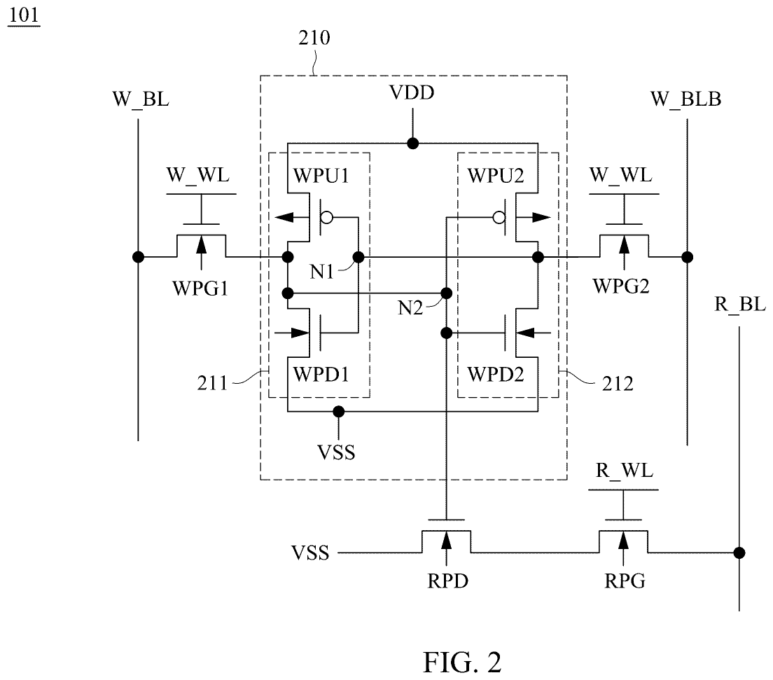

Reference is now made to FIG. 2. FIG. 2 is a schematic diagram of an example of the bit cell 101 corresponding to the memory device 100 in FIG. 1, in accordance with some embodiments of the present disclosure. With respect to the embodiments of FIG. 1, like elements in FIG. 2 are designated with the same annotations and/or reference numbers for ease of understanding. The specific operations of similar elements, which are already discussed in detail in above paragraphs, are omitted herein for the sake of brevity.

As shown in FIG. 2, in some embodiments, the bit cell 101 is a two-port eight-transistor (8T) bit cell having a write port and a read port. For illustration, the bit cell 101 includes a latch 210, a transistor WPG1, a transistor WPG2, a transistor RPG and a transistor RPD. The latch 210, the transistor WPG1 and the transistor WPG2 correspond to the write port of the bit cell 101 for writing data to the bit cell 101. The transistor RPG and the transistor RPD correspond to the read port of the bit cell 101 for reading data from the bit cell 101. In some embodiments, the devices (e.g., transistors) of the bit cell 101 are gate-all-around (GAA) devices.

A gate terminal of the transistor WPG1 is coupled to the write word line W_WL. A source/drain terminal of the transistor WPG1 is coupled to the write bit line W_BL. A drain/source terminal of the transistor WPG1 is coupled to the latch 210. Similarly, a gate terminal of the transistor WPG2 is coupled to the write word line W_WL. A source/drain terminal of the transistor WPG2 is coupled to the write bit line W_BLB. A drain/source terminal of the transistor WPG2 is coupled to the latch 210.

In some embodiments, the latch 210 includes an inverter 211 and an inverter 212. The inverters 211 and 212 are coupled to a supply voltage VDD and a supply voltage VSS. The inverters 211 and 212 operate with a supply voltage VDD and a supply voltage VSS. In some embodiments, the supply voltage VDD is higher than the supply voltage VSS. In some embodiments, the supply voltage VSS is a ground voltage.

The inverters 211 and 212 are cross-coupled to each other. Specifically, an input terminal of the inverter 211, an output terminal of the inverter 212 and the drain/source terminal of the transistor WPG2 are coupled together as a node N1. Similarly, an output terminal of the inverter 211, an input terminal of the inverter 212 and the drain/source terminal of the transistor WPG1 are coupled together as a node N2.

The voltages of the nodes N1 and N2 indicate a bit of data stored in the bit cell 101. For example, when the node N1 has a logic high voltage level and the node N2 has a logic low voltage level, the bit cell 101 stores a first logic value (“0” or “1”). On the contrary, when the node N1 has the logic low voltage level and the node N2 has the logic high voltage level, the bit cell 101 stores a second logic value inverted to the first logic value.

In some embodiments, the inverter 211 includes a transistor WPU1 and a transistor WPD1. The inverter 212 includes a transistor WPU2 and a transistor WPD2. As shown in FIG. 2, a source/drain terminal of the transistor WPU1 is coupled to the supply voltage VDD. A drain/source terminal of the transistor WPD1 is coupled to the supply voltage VSS. A drain/source terminal of the transistor WPU1 and a source/drain terminal of the transistor WPD1 are coupled together as the input terminal of the inverter 211. A gate terminal of the transistor WPU1 and a gate terminal of the transistor WPD1 are coupled together as the input terminal of the inverter 211.

Similarly, a source/drain terminal of the transistor WPU2 is coupled to the supply voltage VDD. A drain/source terminal of the transistor WPD2 is coupled to the supply voltage VSS. A drain/source terminal of the transistor WPU2 and a source/drain terminal of the transistor WPD2 are coupled together as the input terminal of the inverter 211. A gate terminal of the transistor WPU2 and a gate terminal of the transistor WPD2 are coupled together as the input terminal of the inverter 211.

As shown in FIG. 2, a gate terminal of the transistor RPG is coupled to the read word line R_WL. A source/drain terminal of the transistor RPG is coupled to the read bit line R_BL. A drain/source terminal of the transistor RPG is coupled to a source/drain terminal of the transistor RPD. A gate terminal of the transistor RPD is coupled to the node N2. A drain/source terminal of the transistor RPD is coupled to the supply voltage VSS.

In some embodiments, the transistors WPG1, WPG2, WPD1, WPD2, RPD and RPG are of a first conductive type. The transistors WPU1 and WPU2 are of a second conductive type different from the first conductive type. In some embodiments, the transistors WPG1, WPG2, WPD1, WPD2, RPD and RPG are n type metal-oxide-semiconductor field-effect transistors (NMOS). The transistors WPU1 and WPU2 are p type metal-oxide-semiconductor field-effect transistors (PMOS).

In some embodiments, the transistors WPU1 and WPU2 are pull-up devices. Specifically, the transistor WPU1 is turned on to pull up the voltage of the node N2 in response to the node N1 having a logic low voltage level. Similarly, the transistor WPU2 is turned on to pull up the voltage of the node N1 in response to the node N2 having a logic low voltage level.

In some embodiments, the transistors WPD1, WPD2 and RPD are pull-down devices. Specifically, the transistor WPD1 is turned on to pull down the voltage of the node N2 in response to the node N1 having a logic high voltage level. Similarly, the transistor WPD2 is turned on to pull down the voltage of the node N1 in response to the node N2 having a logic high voltage level. The transistor RPD is turned to pull-down the voltage of the drain/source terminal of the transistor RPG.

According to some embodiments of the present disclosure, in a write operation, a write word line signal is transmitted through the write word line W_WL to activate the bit cell 101. For example, in the write operation, a voltage level of the write word line W_WL is pulled high to turn on the transistors WPG1 and WPG2 and the bit cell 101 is activated. When the transistors WPG1 and WPG2 are turned on (bit cell 101 activated), a bit of data transmitted by the bit lines W_BL and W_BLB are programed into the bit cell 101. Then, the transistors WPG1 and WPG2 are turned off. The bit cell 101 stores the bit of data by maintaining the voltage levels of the node N1 and N2. In some embodiments, in a write operation, the logic levels of voltages on the bit lines W_BL and W_BLB are inverted to each other.

In a read operation, a read word line signal is transmitted through the read word line R_WL to activate the bit cell 101. For example, in the read operation, a voltage level of the read word line R_WL is pulled high to turn on the transistor RPG and the bit cell 101 is activated. When the transistor RPG is turned on (bit cell 101 activated), a voltage level on the read bit line R_BL is adjusted according to the data stored in the bit cell 101 (the voltage level of the node N2).

Specifically, in some embodiments, the read bit line R_BL is precharged in a read operation to have a logic high voltage level. When the voltage of the node N2 has a logic high voltage level, the transistor RPD is turned on and the voltage level on the read bit line R_BL is pulled down. On the contrary, when the voltage of the node N2 has a logic low voltage level, the transistor RPD is turned off and the voltage on the read bit line R_BL has the logic high voltage level. Accordingly, when the bit cell 101 is activated in the read operation, the voltage level of the read bit line R_BL is associated with the voltage of the node N2, and thus the voltage level of the read bit line R_BL indicates the data stored in the bit cell 101.

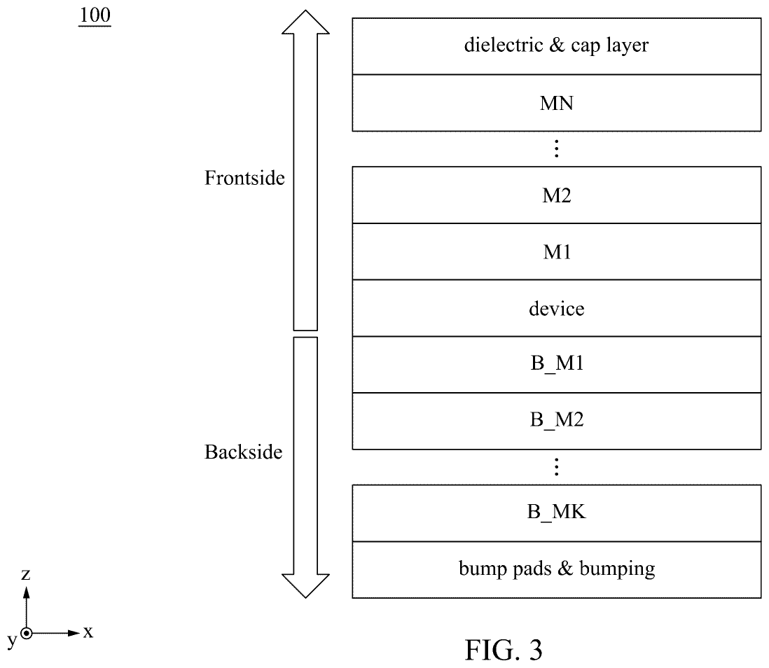

In some embodiments, the memory device 100 is referred to as an integrated circuit structure including active semiconductor devices (i.e., with drain/source structure implements with active areas, gate structures, metal-on-device MD on the active areas, etc.) and front side metal routing on its front side and some metal routing on its backside. In some embodiments, the active semiconductor device on the front side of the memory device 100 is formed on a substrate in a front side process. After the front side process is complete, the memory device 100 is flipped upside down, such that a backside surface of the substrate faces upwards. The substrate is further thinned down and removed. In some embodiments, thinning is accomplished by a chemical mechanical planarization (CMP) process, a grinding process, or the like. Accordingly, backside process is performed to form structures on the backside of the memory device 100. Further detail about layers of the memory device 100 is described in the following paragraphs with reference to FIG. 3.

Reference is now made to FIG. 3. FIG. 3 is a schematic diagram of layers of the memory device 100 corresponding to FIGS. 1-2, in accordance with some embodiments of the present disclosure. With respect to the embodiments of FIGS. 1-2, like elements in FIG. 3 are designated with the same annotations and/or reference numbers for ease of understanding. For illustration, the front side of the memory device 100 includes a device layer, a number “N” of metal layers M1-MN and a dielectric and cap layer.

The backside of the memory device 100 includes a number “K” of backside metal layers B_M1-B_MK, bump pads and bumping. In some embodiments, the number “K” and the number “N” are different.

As shown in FIG. 3, the layers are stacked along a vertical direction z. The metal layer M1 (the first metal layer, i.e., metal one layer) is above the device layer, the metal layer M2 (the second metal layer, i.e., metal two layer) is above the metal layer M1 . . . and the metal layer MN (the N-th metal layer) is above the metal layer MN−1. The dielectric and cap layer is above the metal layer MN.

The backside metal layer B_M1 (the first backside metal layer, i.e., backside metal one layer) is under the device layer, the backside metal layer B_M2 (the second backside metal layer, i.e., backside metal two layer) is under the backside metal layer B_M1 . . . and the backside metal layer B_MK is under the backside layer B_MK−1. The bump pads and bumping are under the backside metal layer B_MK.

In some embodiments, the device layer includes a gate layer, an oxide diffusion (OD) layer, front side contact layers, a via0 layer, backside contact layers, and a backside via0 (B_via0) layer. The OD layer includes active areas. The front side contact layers include contacts that couple gates and/or active areas to front side metal routing. The via0 layer includes the vias that couple the front side contact to the metal layer M1. The backside contact layers include contacts that couple gates and/or active areas to backside metal routing. The B_via0 layer includes the vias that couple the active areas to the backside metal layer B_M1.

In some embodiments, the dielectric and cap layer are formed with silicon (Si). The bump pads and bumping include input/output (I/O) pads, power pads and solder bumping (e.g., Al pad, Cu pad or Ni pad), passivation layer, under-bump metallization (UBM), redistribution layer (RDL) and bump balls.

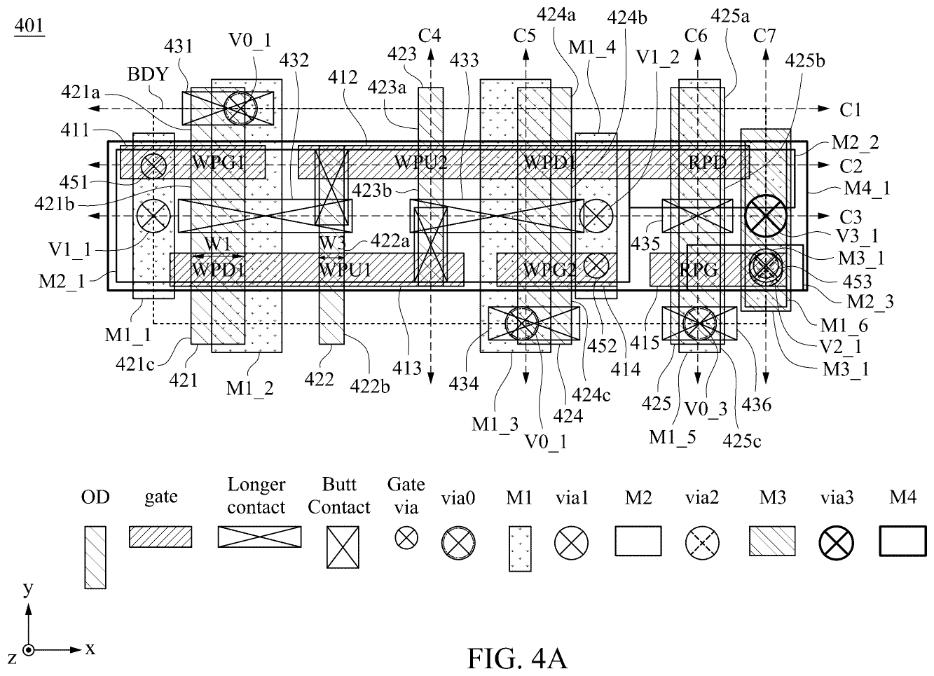

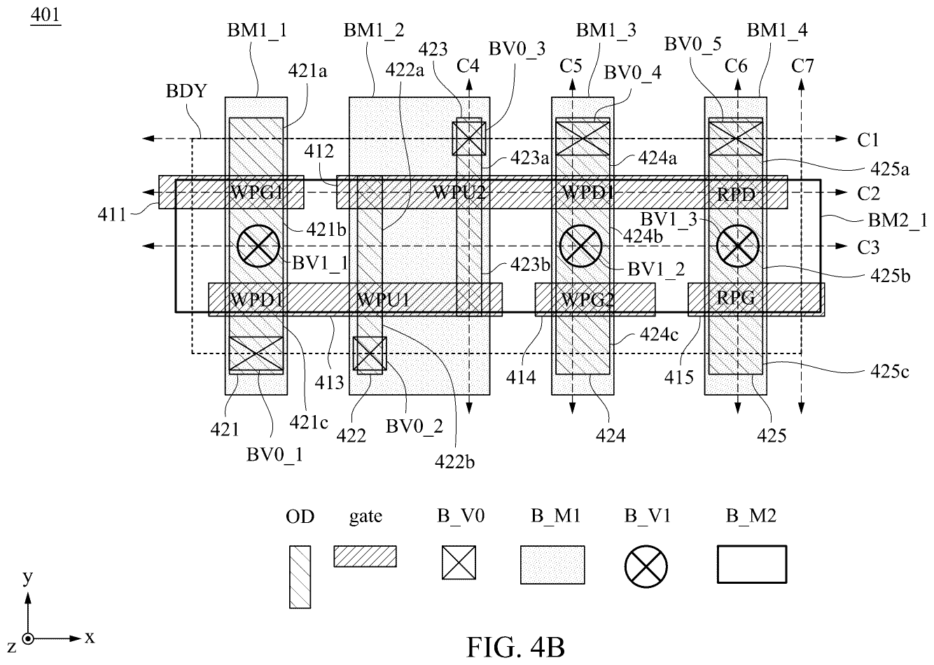

In the following paragraphs, examples of semiconductor layout of front side and backside corresponding to bit cell configured with respect to the bit cell 101 of the memory device 100 are described with reference to FIGS. 4A-4B, 5A-5G, 6A-6B, 7A-7B, 8A-8B and 9A-9B.

Reference is now made to FIGS. 4A-4B. FIG. 4A is a layout diagram corresponding to front side of a bit cell 401 configured with respect to the bit cell 101 of memory device 100 of FIGS. 1-3, in accordance with some embodiments of the present disclosure. FIG. 4B is a layout diagram corresponding to backside of the bit cell 401, in accordance with some embodiments of the present disclosure. With respect to the embodiments of FIGS. 1-3, like elements in FIGS. 4A-4B are designated with the same annotations and/or reference numbers for ease of understanding.

As shown in FIG. 4A, the boundary BDY corresponds to the cell boundary of the bit cell 401. The bit cell 401 includes gates 411-415, OD areas 421-425, longer contacts 431-435, butt contacts 441-442, gate vias 451-453, vias V0_1-V0_3, metal lines M1_1-M1_6, vias V1_1-V1_3, metal lines M2_1-M2_3, a via V2_1, a metal line M3_1, a via V3_1 and a metal line M4_1.

The gates 411-415 are gate structures extending along the direction x in the gate layer. The OD areas 421-425 are active areas extending along the direction y in the OD layer. The OD area 421 includes OD regions 421a, 421b and 421c. The OD area 422 includes OD regions 422a and 422b. The OD area 423 includes OD regions 423a and 423b. The OD area 424 includes OD regions 424a, 424b and 424c. The OD area 425 includes OD regions 425a, 425b and 425c.

In some embodiments, the OD regions 421a-421c, 424a-424c and 425a-425c are of a first conductive type. The OD regions 422a-422b and 423a-423b are of a second conductive type different from the first conductive type. In some embodiments, the OD regions 421a-421c, 424a-424c and 425a-425c are n-type and the OD regions 422a-422b and 423a-423b are p-type.

The gate 411 corresponds the gate terminal of the transistor WPG and the OD regions 421a-421b correspond to source/drain terminals of the transistor WPG.

The gate 412 corresponds the gate terminal of the transistor WPU2 and the OD regions 423a-423b correspond to source/drain terminals of the transistor WPU2. The gate 412 further corresponds the gate terminal of the transistor WPD2 and the OD regions 424a-424b correspond to source/drain terminals of the transistor WPD2. The gate 412 further corresponds the gate terminal of the transistor RPD and the OD regions 425a-425b correspond to source/drain terminals of the transistor RPD.

The gate 413 corresponds the gate terminal of the transistor WPD1 and the OD regions 421b-421c correspond to source/drain terminals of the transistor WPD1. The gate 413 further corresponds the gate terminal of the transistor WPU1 and the OD regions 422a-422b correspond to source/drain terminals of the transistor WPU1.

The gate 414 corresponds the gate terminal of the transistor WPG2 and the OD regions 424b-424c correspond to source/drain terminals of the transistor WPG2.

The gate 415 corresponds the gate terminal of the transistor RPG and the OD regions 425b-425c correspond to source/drain terminals of the transistor RPG.

In some embodiments, each of the OD areas 421, 424 and 425 has a width W1 along the direction x. Each of the OD areas 422 and 423 has a width W2 along the direction x. In some embodiments, the width W1 is greater than the width W2.

According to some embodiments of the present disclosure, the longer contacts 431-436 are contacts that connect to the OD areas. For example, the longer contact 431 is coupled to the OD region 421a. The longer contact 432 is coupled to the OD region 421b and the OD region 422a. The longer contact 433 is coupled to the OD region 423b and the OD region 424b. The longer contact 434 is coupled to the OD region 424c. The longer contact 435 is coupled to the OD region 425b. The longer contact 436 is coupled to the OD region 425c.

The butt contacts 441 and 442 are contacts that connect a longer contact and a gate. For example, the butt contact 441 is coupled between the gate 412 and the longer contact 432. The butt contact 442 is coupled between the gate 413 and the longer contact 433.

The metal lines M1-1-M1_6 are metal lines extending along the direction y in the metal layer M1. In some embodiments, the metal line M1_2 corresponds to the write bit line W_BL. The metal line M1_3 corresponds to the write bit line W_BLB. The metal line M1_5 corresponds to the read bit line R_BL.

The gate vias 451-453 are vias that connect a gate to a metal line in the metal layer M1. For example, the gate via 451 is coupled between the gate 411 and the metal line M1_1. The gate via 452 is coupled between the gate 414 and the metal line M1_4. The gate via is coupled between the gate 415 and the metal line M1_6.

The vias V0_1-V0_3 are vias in the via0 layer. The vias in the via0 layer connect longer contacts to the metal lines in the metal layer M1. For example, the via V0_1 is coupled between the longer contact 431 and the metal line M1_2. The via V0_2 is coupled between the longer contact 434 and the metal line M1_3. The via V0_3 is coupled between the longer contact 436 and the metal line M1_5.

The metal lines M2-1-M2_3 are metal lines extending along the direction x in the metal layer M2. In some embodiments, the metal line M2_1 is coupled to the metal line M2_2. In some embodiments, the metal lines M2_1 and M2_2 correspond to the write word line W_WL.

The vias V1_1-V1_3 are vias in a via1 layer. The vias in the via1 layer connect metal lines in the metal layer M1 to metal lines in the metal layer M2. For example, the via V1_1 is coupled between the metal line M1_1 and the metal line M2_1. The via V1_2 is coupled between the metal line M1_4 and the metal line M2_1. The via V1_3 is coupled between the metal line M1_6 and the metal line M2_3.

The metal line M3-1 is a metal line extending along the direction y in the metal layer M3. In some embodiments, the metal line M3-1 corresponds to a landing line of the read word line RWL.

The vias V2_1 is a via in a via2 layer. The vias in the via2 layer connect metal lines in the metal layer M2 to metal lines in the metal layer M3. For example, the via V2_1 is coupled between the metal line M2_3 and the metal line M3_1.

The metal line M4_1 is a metal line extending along the direction x in the metal layer M4. In some embodiments, the metal line M4_1 corresponds to the read word line R_WL.

The vias V3_1 is a via in a via3 layer. The vias in the via3 layer connect metal lines in the metal layer M3 to metal lines in the metal layer M4. For example, the via V3_1 is coupled between the metal line M3_1 and the metal line M4_1.

In some embodiments, the memory device 100 includes multiple bit cells 401 adjacent to each other along the direction x and/or the direction y. In some embodiments, two adjacent bit cells 101 are mirrored to each other about the line of boundary BDY between the two adjacent bit cells 101.

In some embodiments, the memory device 100 include multiple adjacent bit cells 401 corresponding to a row of bit cells 401 along the direction x. The metal line M2_1 of each bit cell 401 extends to contact the metal line M2_1 of an adjacent bit cell 401 along the direction x. The metal line M2_2 of each bit cell 401 extends to contact the metal line M2_2 of the other adjacent bit cell 401 along the direction x. The contacted metal lines M2_1 and M2_2 of multiple bit cells 401 correspond to the write word line W_WL of the row of bit cells 401.

Similarly, the metal line M4_1 of each bit cell 401 extends along the direction x to contact the metal line M4_1 of an adjacent bit cell 401. The contacted metal lines M4_1 of multiple bit cells 401 correspond to the read word line R_WL of the row of bit cells 401.

In some embodiments, the memory device 100 includes multiple adjacent bit cells 401 corresponding to a column of bit cells 401 along the direction y. The metal line M1_2 of each bit cell 401 extends along the direction y to contact the metal line M1_2 of an adjacent bit cell 401. The contacted metal lines M1_2 of multiple bit cells 401 correspond to the write bit line W_BL of the column of bit cells 401.

Similarly, the metal line M1_3 of each bit cell 401 extends along the direction y to contact the metal line M1_3 of an adjacent bit cell 401. The contacted metal lines M1_3 of multiple bit cells 401 correspond to the write bit line W_BLB of the column of bit cells 401. The metal line M1_5 of each bit cell 401 extends along the direction y to contact the metal line M1_5 of an adjacent bit cell 401. The contacted metal lines M1_5 of multiple bit cells 401 correspond to the read bit line R_BL of the column of bit cells 401.

As shown in FIG. 4B, the bit cell 401 further includes backside vias BV0_1-BV0_5, backside metal lines BM1_1-BM1_4, backside vias BV1_1-BV1_3 and a backside metal line BM2_1.

According to various embodiments of the present disclosure, the backside metal lines BM1_1-BM1_4 are metal lines extending along the direction y in the backside metal layer B_M1. In some embodiments, the backside metal lines BM1_1, BM1_3 and BM1_4 correspond to power rails for transmitting the supply voltage VSS. The backside metal line BM1_2 corresponds to the power rail for transmitting the supply voltage VDD.

The backside vias BV0_1-BV0_5 are vias in the B_via0 layer. The vias in the B_via0 layer connect the OD areas to metal lines in the backside metal layer B_M1. For example, the backside via BV0_1 is coupled between the OD region 421c and the backside metal line BM1_1. The backside via BV0_2 is coupled between the OD region 422b and the backside metal line BM1_2. The backside via BV0_3 is coupled between the OD region 423a and the backside metal line BM1_2. The backside via BV0_4 is coupled between the OD region 424a and the backside metal line BM1_3. The backside via BV0_5 is coupled between the OD region 425a and the backside metal line BM1_4.

The backside metal line BM2_1 is a metal line extending along the direction x in the backside metal layer B_M2. The backside vias BV1_1-BV1_3 are vias in a backside via1 (B_via1) layer. The vias in the B_via1 layer connect the metal lines in the backside metal layer B_M1 to metal lines in the backside metal layer B_M2.

In some embodiments, the metal line BM2_1 of each bit cell 401 extends along the direction x to contact the metal line BM2_1 of an adjacent bit cells 401 in a same row. The contacted metal lines BM2_1 of multiple bit cells 401 transmit the supply voltage VSS to bit cells 401 in the same row.

In some embodiments, the backside metal lines BM1_1-BM1-4 of each bit cell 401 extends to contact the backside metal lines BM1_1-BM1-4 of an adjacent bit cell 401 in a same column, respectively. The contacted metal lines BM1_1, BM1_3 and BM1_4 of multiple bit cells 401 transmit the supply voltage VSS to bit cells 401 in the same column. The contacted metal lines BM1_2 of multiple bit cells 401 transmit the supply voltage VDD to bit cells 401 in the same column.

In some embodiments, the backside of the bit cell 401 is for metal lines conducting supply voltages VSS and VDD. Being placed at the backside instead of being placed at the front side with other lines (e.g., the write bit lines W_BL), the metal lines for supply voltages can be designed with greater width. Therefore, metal resistance can be lowered to improve speed and chip power IR drop is reduced).

In some embodiments, the metal lines for the supply voltages VDD and VSS are arranged in the backside metal layer B_M1, for example, the backside metal lines BM1_1-BM1-4. In some embodiments, the metal lines in the backside metal layer B_M2 are coupled to the metal lines of the supply voltage VSS to minimize the IR drop of the node of the supply voltage VSS (through forming a robust power mesh with the metal lines in metal layer M1). For example, the backside metal lines BM1_1-BM1-4 and BM2_1 form a power mesh.

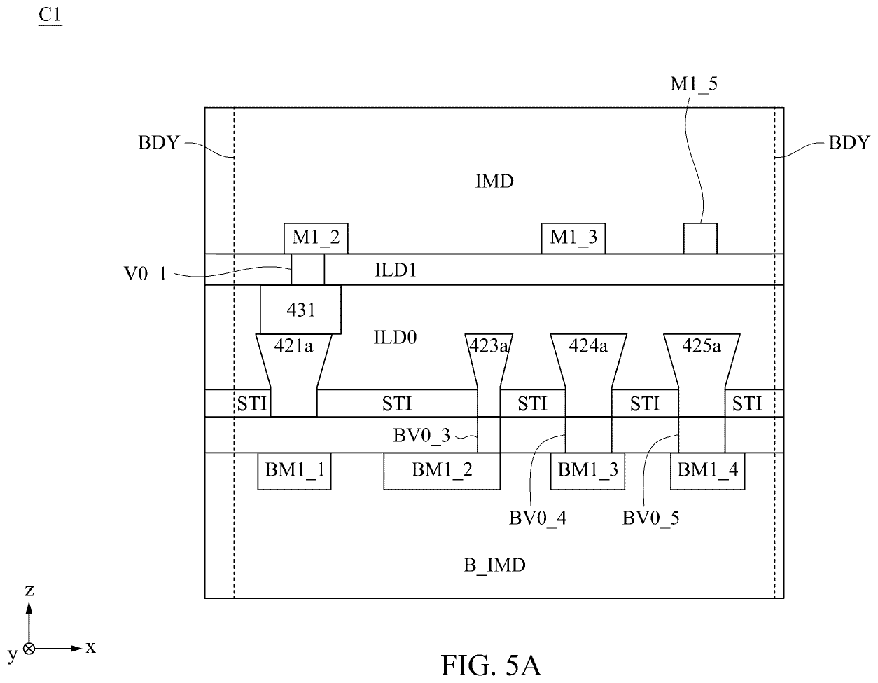

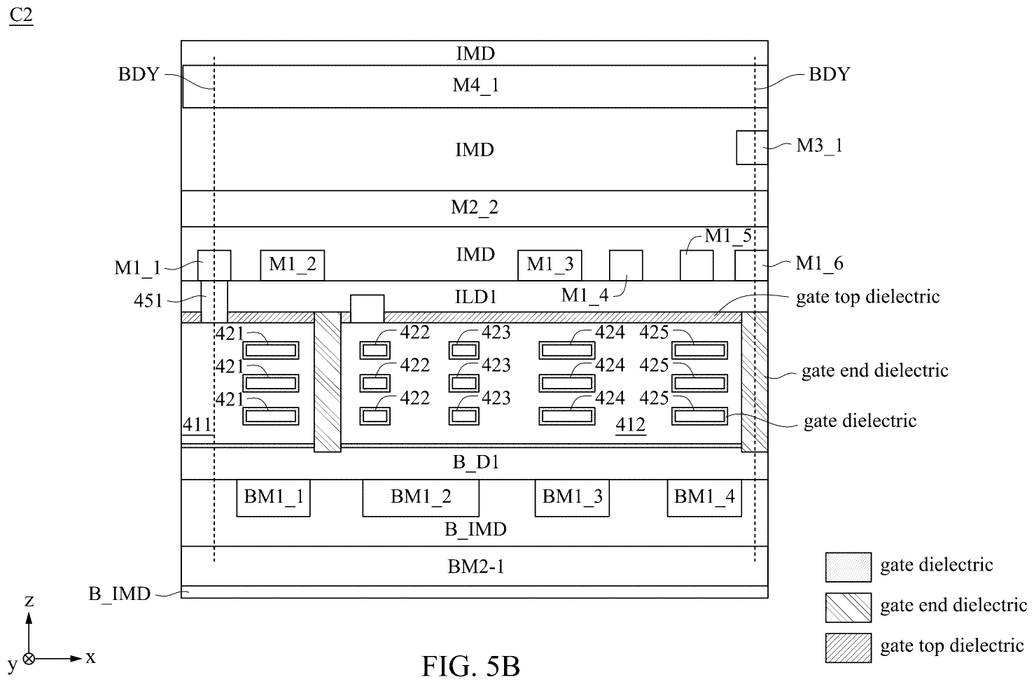

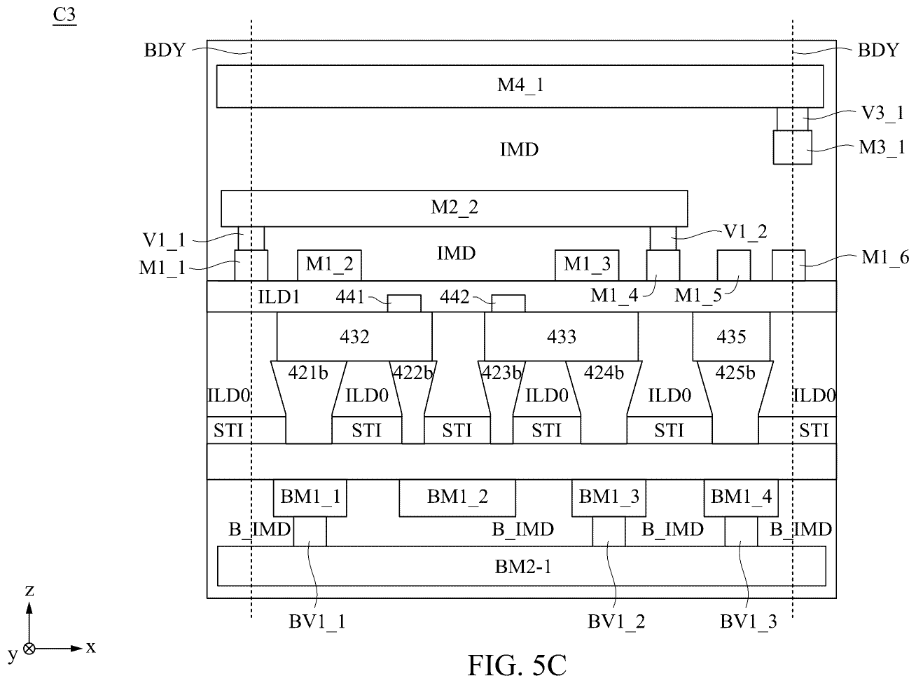

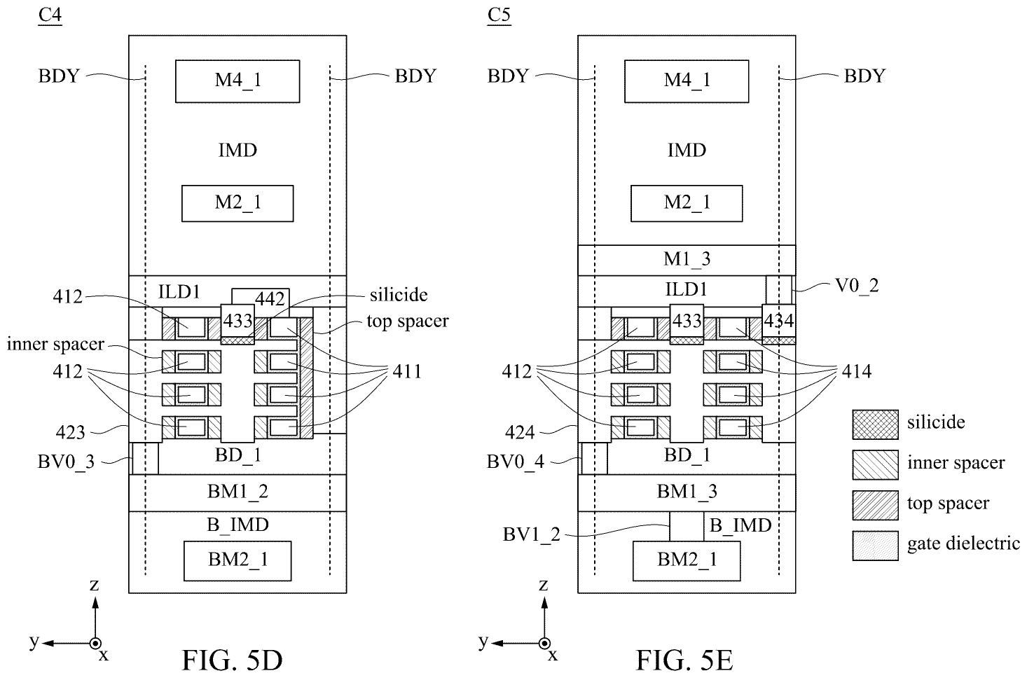

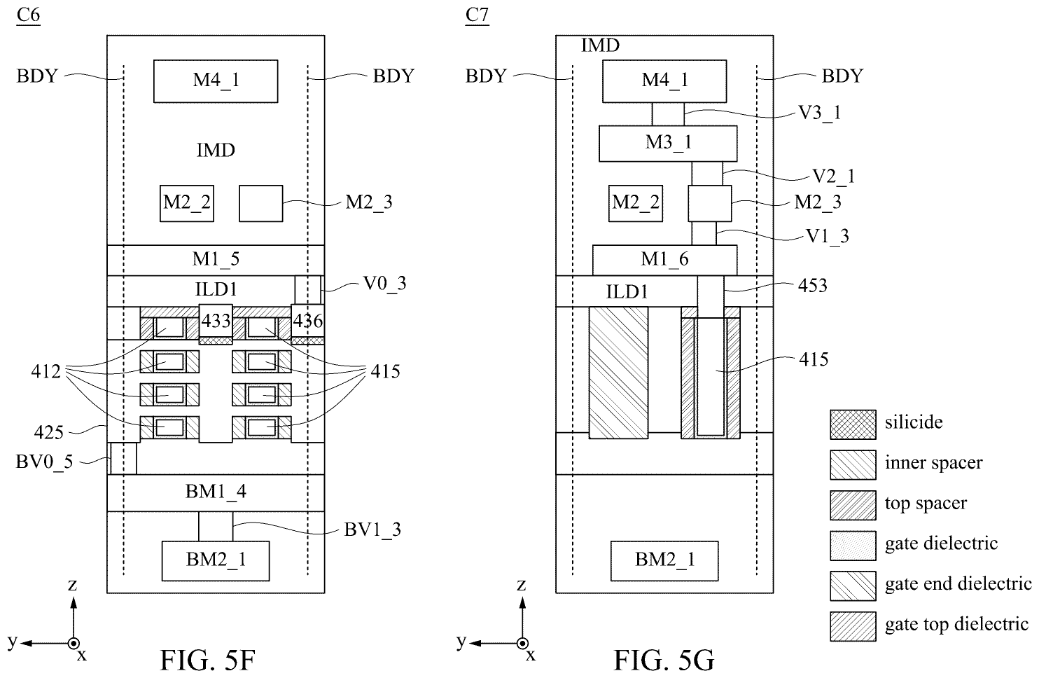

In the following paragraphs, further details about the layout of the bit cell 401 in cross-section views along the lines C1-C7 are described with further reference to FIGS. 5A-5G.

Reference is now made to FIG. 5A. FIG. 5A is a schematic diagram corresponding to a cross-section view along the line C1 of the bit cell 401 of FIGS. 4A-4B, in accordance with some embodiments of the present disclosure. With respect to the embodiments of FIGS. 1-3 and 4A-4B, like elements in FIG. 5A are designated with the same annotations and/or reference numbers for ease of understanding.

As shown in FIG. 5A, the metal lines in the backside metal layer B_M1 is surrounded by backside inter-metal dielectric (IMD) B_IMD. The backside metal layer B_M1 and the backside IMD B_IMD are covered by backside dielectric B_D1. In some embodiments, the backside IMD B_IMD and the backside dielectric B_D1 have different materials. For example, each of the backside metal lines BM1_1-BM1_4 is surrounded by the backside IMD and the top surface of each of the backside metal lines BM1_1-BM1_4 is covered by the backside dielectric B_D1.

The vias of the backside via layer is in the backside dielectric B_D1. For example, the backside vias BV0_3-BV0_5 are in the backside dielectric B_D1.

The backside via0 layer and the backside dielectric B_D1 are covered by shallow trench isolation (STI). The STI is covered by inter-layer dielectric ILD0. In some embodiments, a lower portion of each of the OD areas is in the STI and an upper portion of each of the OD areas is in the inter-layer dielectric ILD0. In some embodiments, the epitaxy (EPI) of each of the OD areas is formed at the upper portion in the inter-layer dielectric ILD0.

For example, lower portions of the OD regions 421a, 423a, 424a and 425a are in the STI. Upper portions of the OD regions 421a, 423a, 424a and 425a are in the inter-layer dielectric ILD0.

As shown in FIG. 5A, the longer contacts are above the OD areas and are in the inter-layer dielectric ILD0. For example, the longer contact 431 is above the OD region 421a and is in the inter-layer dielectric ILD0.

The inter-layer dielectric ILD0 and the longer contacts are covered by inter-layer dielectric ILD1. In some embodiments, the inter-layer dielectric ILD0 and the inter-layer dielectric ILD1 have different materials. The via0 layer is in the inter-layer dielectric ILD1. For example, the via V0_1 is above the longer contact 431 and in the inter-layer dielectric ILD0.

The inter-layer dielectric ILD1 and the via0 layer are covered by inter-metal dielectric IMD. The metal layer M1 is in the inter-metal dielectric IMD. For example, the metal lines M1_2, M1_3 and M1_5 are above the inter-layer dielectric ILD1 and in the inter-metal dielectric IMD. In some embodiments, the inter-layer dielectric ILD0, the inter-layer dielectric ILD1 and the inter-metal dielectric IMD have different materials.

Reference is now made to FIG. 5B. FIG. 5B is a schematic diagram corresponding to a cross-section view along the line C2 of the bit cell 401 of FIGS. 4A-4B, in accordance with some embodiments of the present disclosure. With respect to the embodiments of FIGS. 1-3, 4A-4B and 5A like elements in FIG. 5B are designated with the same annotations and/or reference numbers for ease of understanding.

As shown in FIG. 5B, the backside metal layers are formed in the backside IMD B_IMD. The backside metal layers are separated from each other by the backside IMD B_IMD along the direction z. For example, the backside metal layer B_M2 is in the backside IMD B_IMD and separated from the backside metal layer BM_1 by the backside IMD B_IMD.

The gates are above the backside dielectric B_D1. Different gates are separated by gate end dielectric. For example, the gate 411 and the gate 412 are separated by the gate end dielectric.

In some embodiments, the OD areas extend through the gates. For example, the OD area 421 extends through the gate 411. The OD areas 422-425 extend through the gate 412. As shown in FIG. 5B, the portion of each OD area in a gate may be a fin or separated wires or sheets like nano-wires, nano-sheets, fork-sheets, any suitable structures, or combination thereof. For example, the portion of the OD area 421 in the gate 411 includes three vertically stacked sheets.

In some embodiments, the gates are separated from the OD areas and the backside dielectric B_D1 by gate dielectric including high-k material.

In some embodiments, the gates are covered by gate top dielectric. The gate top dielectric is under the inter-layer dielectric ILD1. The gate end dielectric extends through the gate top dielectric and the gate dielectric along the direction z.

The butt contacts extend through the gate top dielectric to contact the gates. An upper portion of each butt contact is in the inter-layer dielectric ILD1. A top surface of each butt contact is under the inter-layer dielectric ILD1. For example, the butt contact 441 extends through the gate top dielectric and is in the inter-layer dielectric ILD1.

The gate vias extend through the gate top dielectric and the inter-layer dielectric ILD1 to connect the gates and the metal layer M1. For example, the gate via 451 extends through the gate top dielectric and the inter-layer dielectric ILD1 to connect the gate 411 to the metal line M1_1.

The metal layers are in the inter-metal dielectric IMD and separated from each other along the direction z by the inter-metal dielectric IMD. For example, the metal layers M2, M3 and M4 are in the inter-metal dielectric IMD and separated from each other by the inter-metal dielectric IMD.

Reference is now made to FIG. 5C. FIG. 5C is a schematic diagram corresponding to a cross-section view along the line C3 of the bit cell 401 of FIGS. 4A-4B, in accordance with some embodiments of the present disclosure. With respect to the embodiments of FIGS. 1-3, 4A-4B and 5A-5B like elements in FIG. 5C are designated with the same annotations and/or reference numbers for ease of understanding.

As shown in FIG. 5C, the backside vias are in the backside IMD B_IMD and connect different backside metal layers. For example, the backside vias BV1_1-BV1_3 connect the backside metal lines BM1_1, BM1_3, BM1_4 to the backside metal line BM2_1 respectively.

The front side vias are in the inter-metal dielectric IMD and connect different metal layers. For example, the vias V1_1-V1_2 connect the metal lines M1_1 and M1_4 to the metal line M2_1 respectively. The via V3_1 connect the metal line M3_1 to the metal line M4_1.

Reference is now made to FIGS. 5D-5G. FIGS. 5D-5G are schematic diagrams corresponding to cross-section views along the lines C4-C7, respectively, of the bit cell 401 of FIGS. 4A-4B, in accordance with some embodiments of the present disclosure. With respect to the embodiments of FIGS. 1-3, 4A-4B and 5A-5C like elements in FIGS. 5D-5G are designated with the same annotations and/or reference numbers for ease of understanding. The STI is not shown in FIGS. 5D-5G for simplicity.

As shown in FIGS. 5D-5G, the gates are separated from the OD areas by inner spacer along the direction y. Specifically, the gate dielectric is separated from the OD areas by the inner spacer along the direction y. For example, the gate dielectric of the gate 412 is separated from the OD area 423 by the inner spacer along the direction y.

The gates are separated from the inter-layer dielectric ILD0 and the longer contacts by top spacer along the direction y. Specifically, the gate dielectric is separated from the inter-layer dielectric ILD0 and the longer contacts by top spacer along the direction y. For example, the gate dielectric of the gate 412 is separated from the inter-layer dielectric ILD0 by the top spacer along the direction y. In some embodiments, the top spacer and the inner spacer have different materials.

In some embodiments, the butt contact covers the longer contact, the top spacer and the gate. The butt contact extends along the direction y to connect the longer contact to the gate. For example, the butt contact 442 extends to connect the longer contact 433 and the gate 413.

A portion of the longer contact extends into the butt contact. For example, a portion of the longer contact 433 extends into the butt contact 442.

In some embodiments, the longer contact includes silicide contacting the OD area at the bottom of the longer contact. For example, the longer contact 433 includes silicide that contacts the OD area 423.

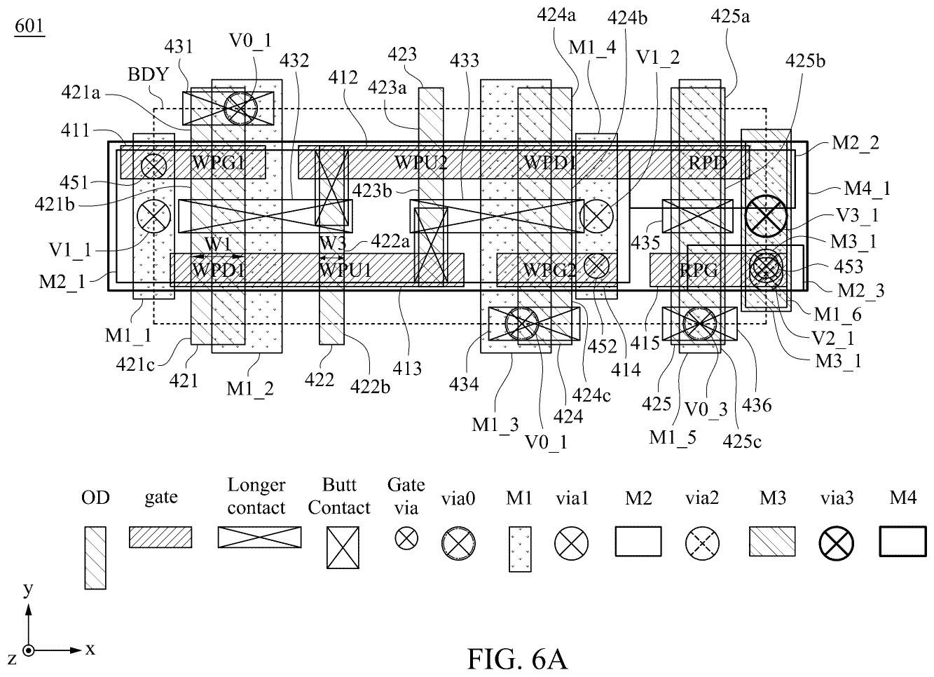

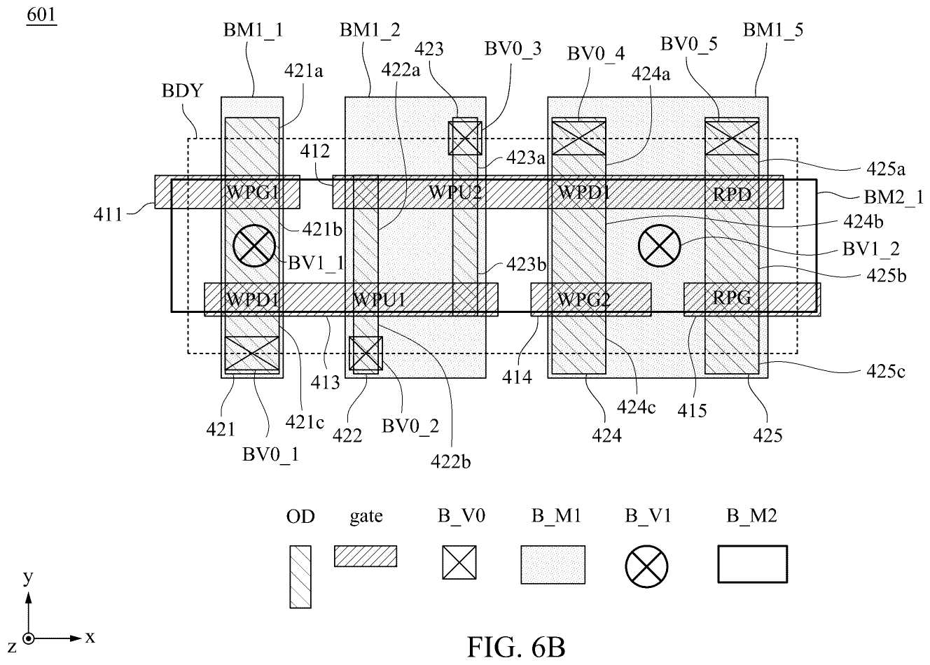

Reference is now made to FIGS. 6A-6B. FIG. 6A is a layout diagram corresponding to front side of a bit cell 601 configured with respect to the bit cell 401 of FIGS. 4A-4B, 5A-5G and the bit cell 101 of FIGS. 1-3, in accordance with some embodiments of the present disclosure. FIG. 6B is a layout diagram corresponding to backside of the bit cell 601, in accordance with some embodiments of the present disclosure. With respect to the embodiments of FIGS. 1-3, 4A-4B and 5A-5G, like elements in FIGS. 6A-6B are designated with the same annotations and/or reference numbers for ease of understanding.

As shown in FIGS. 6A-6B, compared with the bit cell 401, the bit cell 601 has a backside metal line BM1_5 instead of the backside metal lines BM1_3-BM1_4.

The backside metal line BM1_5 is a metal line in the backside metal layer B_M1. The backside metal line BM1_5 are coupled to the OD regions 424a and 425a through the backside vias BV0_4 and BV0_5 respectively to transmit the supply voltage VSS.

In some embodiments, the backside metal line BM1_5 extends along the direction y. In some embodiments, the backside metal line BM1_5 of each bit cell 601 extends to contact an adjacent bit cell 601 in a same column. The contacted backside metal lines BM1_5 transmit the supply voltage VSS to the column of bit cells 601.

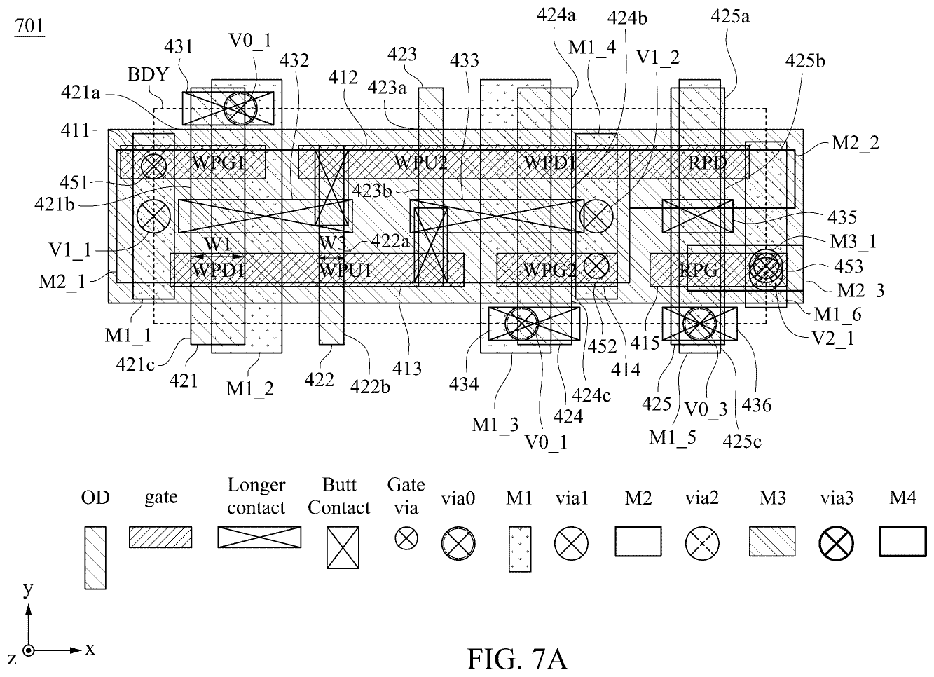

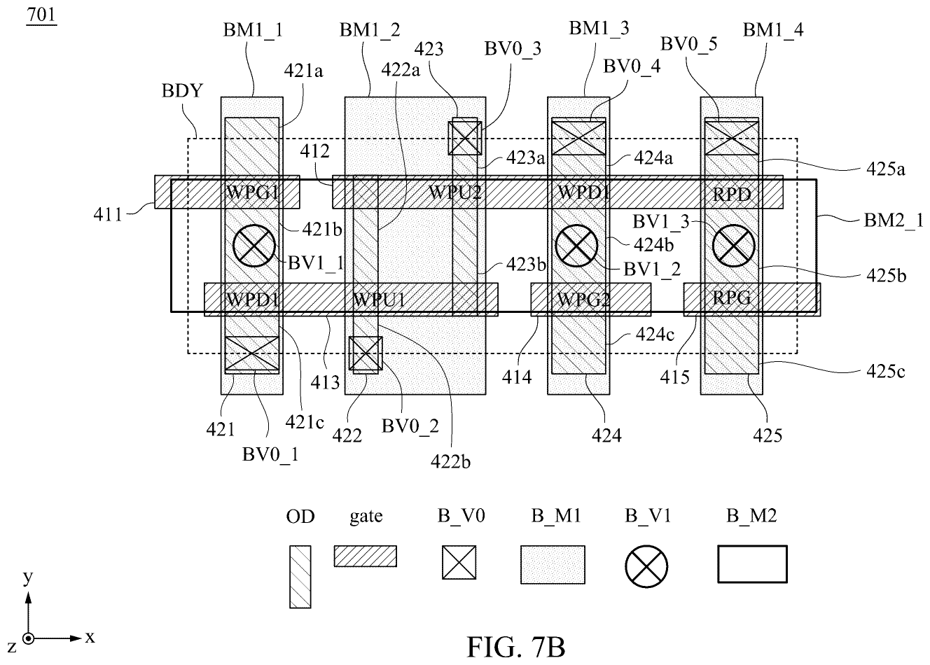

Reference is now made to FIGS. 7A-7B. FIG. 7A is a layout diagram corresponding to front side of a bit cell 701 configured with respect to the bit cell 401 of FIGS. 4A-4B, 5A-5G and the bit cell 101 of FIGS. 1-3, in accordance with some embodiments of the present disclosure. FIG. 7B is a layout diagram corresponding to backside of the bit cell 701, in accordance with some embodiments of the present disclosure. With respect to the embodiments of FIGS. 1-3, 4A-4B and 5A-5G, like elements in FIGS. 7A-7B are designated with the same annotations and/or reference numbers for ease of understanding.

As shown in FIGS. 6A-6B, the difference between the bit cell 401 and the bit cell 701 is that the metal line M3_1 of the bit cell 701 extends along the direction x. The metal line M3_1 of the bit cell 701 is configured as the read word line R_WL instead of the read word line landing line.

In some embodiments, the metal line M3_1 of each bit cell 701 extends to contact an adjacent bit cell 701 in a same row. The contacted metal lines M3_1 correspond to the read word line R_WL of the same row of bit cells 701.

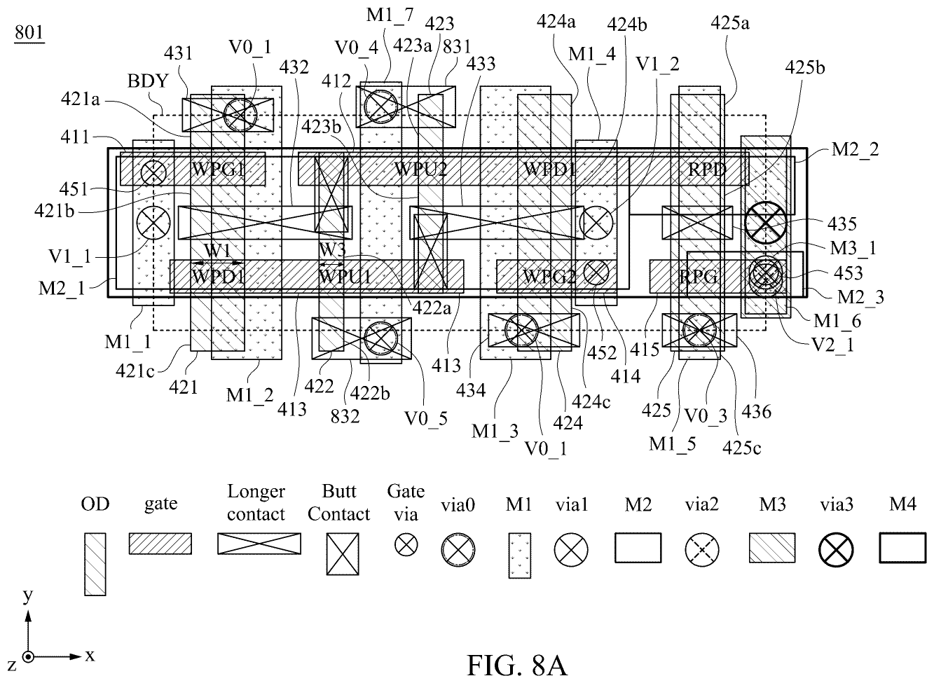

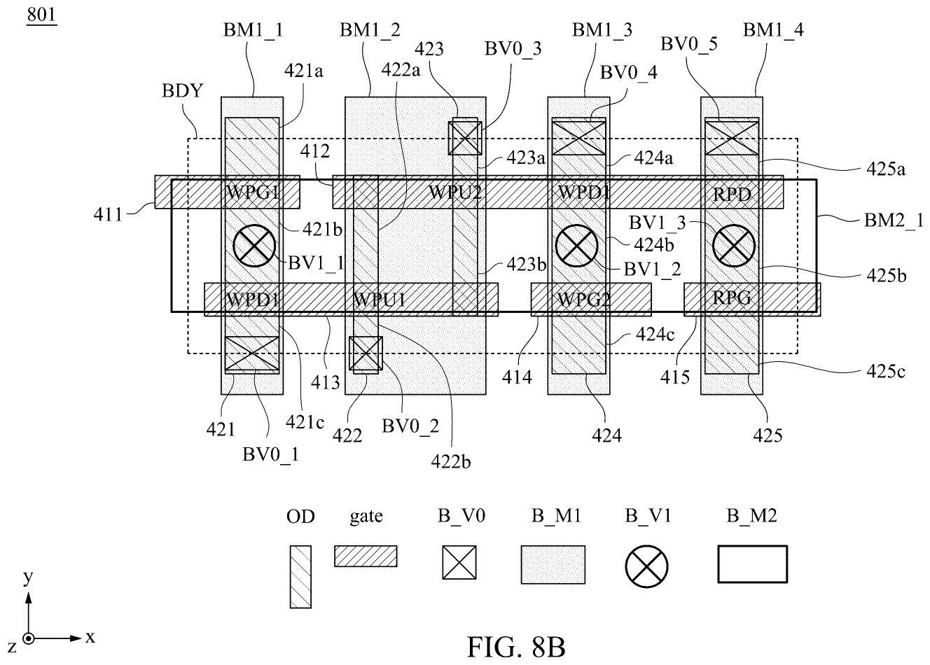

Reference is now made to FIGS. 8A-8B. FIG. 8A is a layout diagram corresponding to front side of a bit cell 801 configured with respect to the bit cell 401 of FIGS. 4A-4B, 5A-5G and the bit cell 101 of FIGS. 1-3, in accordance with some embodiments of the present disclosure. FIG. 8B is a layout diagram corresponding to backside of the bit cell 801, in accordance with some embodiments of the present disclosure. With respect to the embodiments of FIGS. 1-3, 4A-4B and 5A-5G, like elements in FIGS. 8A-8B are designated with the same annotations and/or reference numbers for ease of understanding.

As shown in FIGS. 8A-8B, compared with the bit cell 401, the bit cell 801 further includes a metal line M1_7, vias V0_4-V0_5 and longer contacts 831-832. The metal line M1_7 is a metal line extending along the direction y in the metal layer M1 to transmit the supply voltage VDD.

In some embodiments, the metal line M1_7 of each bit cell 801 extends to contact an adjacent bit cell 801 in a same column. The contacted metal lines M1_7 correspond to a power rail transmitting the supply voltage VDD.

The vias V0_4 and V0_5 are vias in the via0 layer. The vias V0_4 and V0_5 are coupled to the metal line M1_7.

The longer contact 831 extends along the direction x to couple the via V0_4 to the OD region 423a. Similarly, the longer contact 832 extends along the direction x to couple the via V0_5 to the OD region 422b.

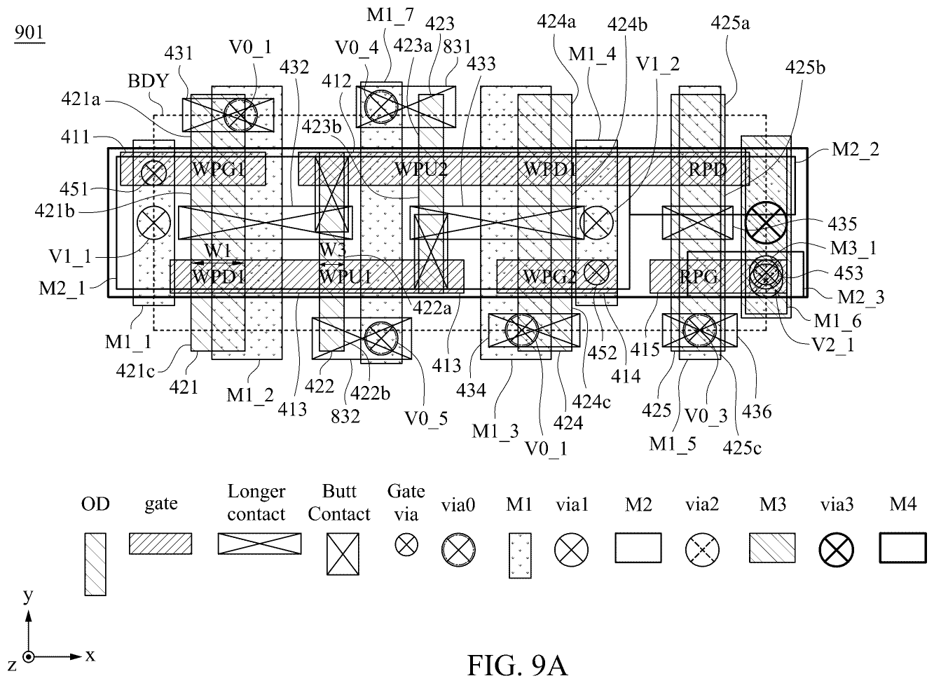

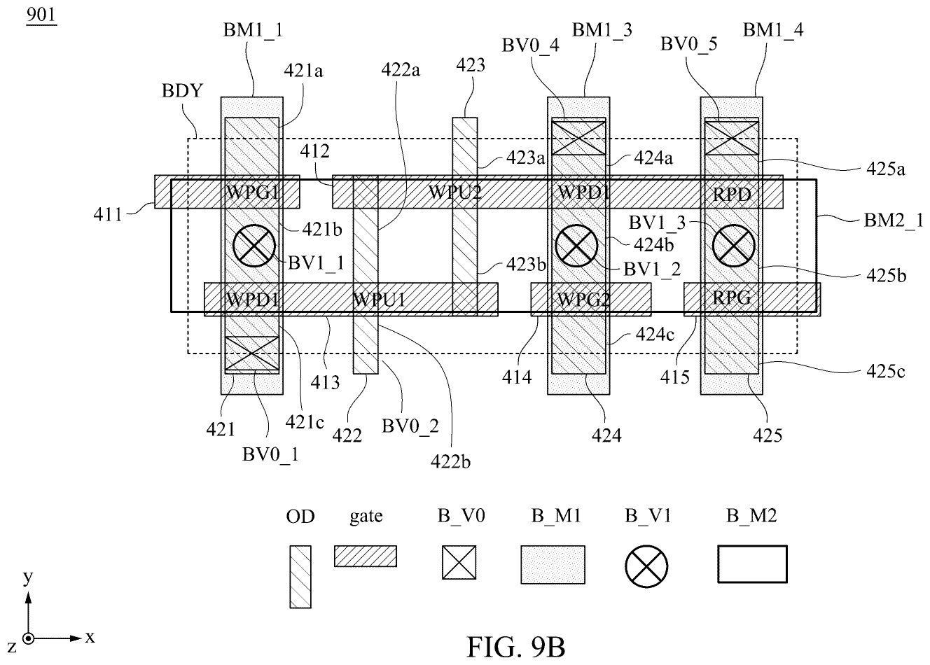

Reference is now made to FIGS. 9A-9B. FIG. 9A is a layout diagram corresponding to front side of a bit cell 901 configured with respect to the bit cell 801 of the FIGS. 8A-8B, the bit cell 401 of FIGS. 4A-4B, 5A-5G and the bit cell 101 of FIGS. 1-3, in accordance with some embodiments of the present disclosure. FIG. 9B is a layout diagram corresponding to backside of the bit cell 901, in accordance with some embodiments of the present disclosure. With respect to the embodiments of FIGS. 1-3, 4A-4B, 5A-5G and 8A-8B, like elements in FIGS. 9A-9B are designated with the same annotations and/or reference numbers for ease of understanding.

As shown in FIGS. 9A-9B, compared with the bit cell 801, the bit cell 901 does not have the backside metal line BM1_2 and backside vias BV0_2-BV0_3 for transmitting the supply voltage VDD. In other words, the VDD conductors are in the front side and the VSS conductors are in the backside.

The configurations of FIGS. 1-3, 4A-4B, 5A-5G, 6A-6B, 7A-7B, 8A-8B, 9A-9B are given for illustrative purposes. Various implements are within the contemplated scope of the present disclosure. For example, in some embodiments, the number of sheets in FIG. 5B is different from three. In some embodiments, the bit cell 401 does not have the gate top dielectric.

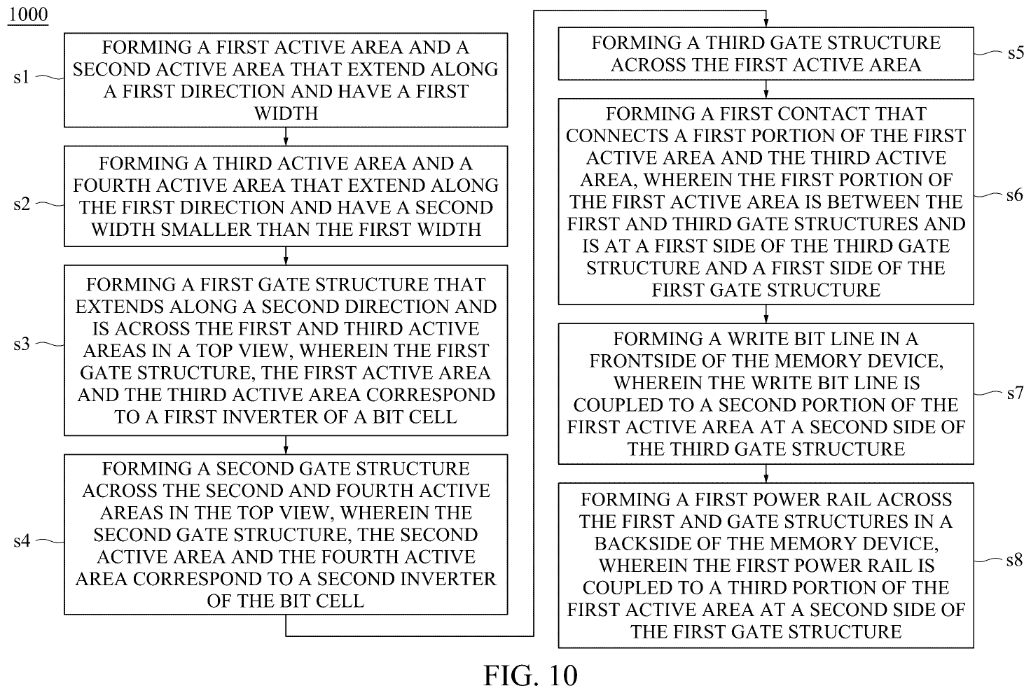

Reference is now made to FIG. 10. FIG. 10 is a flowchart diagram of a method 1000 for manufacturing the memory device 100, bit cells 101, 401, 501, 601, 701, 801 and 901 as shown in FIGS. 1-3, 4A-4B, 5A-5G, 6A-6B, 7A-7B, 8A-8B, 9A-9B, in accordance with some embodiments of the present disclosure. It is understood that additional steps can be provided before, during, and after the steps shown by FIG. 10, and some of the steps described below can be replaced or eliminated, for additional embodiments of the method. The order of the steps may be interchangeable. Some of the steps are performed concurrently. Throughout the various views and illustrative embodiments, like annotations and reference numbers are used to designate like elements. The method 50 includes steps s1-s8 that are described below with reference to the memory device 100, bit cells 101, 401, 501, 601, 701, 801 and 901 corresponding to FIGS. 1-3, 4A-4B, 5A-5G, 6A-6B, 7A-7B, 8A-8B, 9A-9B.

In step s1, the OD area 421 and the OD area 424 that extend along the direction y and have the width W1 are formed.

In step s2, the OD area 422 and the OD area 423 that extend along the direction y and have the width W2 smaller than the width W1 are formed.

In step s3, the gate 413 that extends along the direction x and is across the OD areas 421, 422 and 423 in a top view (layout view) are formed. The OD areas 421-422 and the gate 413 correspond to the inverter 211 of a bit cell 101.

In step s4, the gate 412 that extends along the direction x and is across the OD areas 422, 423 and 424 in the top view are formed. The OD areas 423-424 and the gate 412 correspond to the inverter 212 of the bit cell 101.

In step s5, the gate 411 across the OD area 421 in the top view is formed.

In step s6, the longer contact 432 that connects the OD region 421b (a portion of the OD area 421 between the gates 411 and 413) and the OD region 422a (a portion of the OD area 422 between the gates 412 and 413) is formed.

In step s7, the write bit line W_BL is formed in the front side of the memory device 100. Specifically, the metal line M1_2 in the metal one layer is formed as the write bit line W_BL. The write bit line W_BL (the metal line M1_2) is coupled to the OD region 421a beside the gate 411.

In step s8, a backside metal line BM1_1 in the backside metal one layer is formed as a power rail for transmitting the supply voltage VSS. The power rail (backside metal line BM1_1) is coupled to the OD region 421c.

In some embodiments, the method 1000 further comprises: forming the write word line W_WL extending along the second direction in the metal two layer. The write word line W_WL is coupled to the gate 411.

In some embodiments, the method 1000 further comprises the following steps: forming the write word line W_WL that extends along the second direction in the metal two layer and is coupled to the gate 411; forming the gate 414 across the OD area 424; forming the longer contact 433 that connects the OD region 424b (a portion of the OD area 424 between the gates 412 and 413) and the OD region 423b (a portion of the OD area 423 between the gates 411 and 412); and forming a complementary write bit line W_BLB in the front side. The complementary write bit line W_BLB is coupled the OD region 424c beside the gate 414.

In some embodiments, the method 1000 further comprises the following steps: forming the OD area 425 extending along the direction y, the gate 412 extending across the OD area 425; forming the gate 415 across the OD area 425; and forming the read word line R_WL coupled to the gate 415.

In some embodiments, the read word line R_WL is formed in the metal layer M4 and the metal layer M4 of the memory device 100 only has read word lines R_WL. In some embodiments, the read word line R_WL is formed in the metal layer M3 and the metal layer M3 of the memory device 100 only has read word lines R_WL.

In some embodiments, the method 1000 further comprises: forming the read bit line R_BL coupled to the OD region 425c.

In some embodiments, the write bit lines W_BL, W_BLB and the read bit lines R_BL are formed in the metal layer M2. In some embodiments, the metal layer M2 only has the write bit lines W_BL, W_BLB and the read bit lines R_BL.

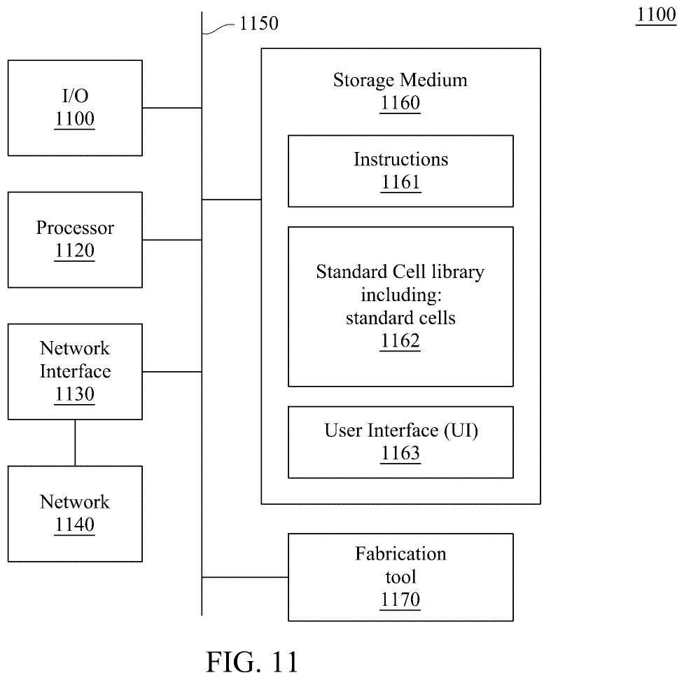

Reference is now made to FIG. 11. FIG. 11 is a block diagram of an electronic design automation (EDA) system 1100 for designing the integrated circuit layout design, in accordance with some embodiments of the present disclosure. The EDA system 1100 is configured to implement one or more steps of the method 1000 disclosed in FIG. 10, and layout design disclosed in FIGS. 4A-4B, 5A-5G, 6A-6B, 7A-7B, 8A-8B and 9A-9B.

In some embodiments, the EDA system 1100 is a general purpose computing device including a hardware processor 1120 and a non-transitory, computer-readable storage medium 1160. The storage medium 1160, amongst other things, is encoded with, i.e., stores, instructions (computer program code) 1161, i.e., a set of executable instructions. Execution of the instructions 1161 by hardware processor 1120 represents (at least in part) an EDA tool which implements a portion or all of, e.g., the method 1000, and method for implementing layout design disclosed in FIGS. 4A-4B, 5A-5G, 6A-6B, 7A-7B, 8A-8B and 9A-9B.

The processor 1120 is electrically coupled to the storage medium 1160 via a bus 1150. The processor 1120 is also electrically coupled to an input/output (I/O) interface 1110 and a fabrication tool 1170 by bus 1150. A network interface 1130 is also electrically connected to processor 1120 via bus 1150. Network interface 1130 is connected to a network 1140, so that processor 1120 and the storage medium 1160 are capable of connecting to external elements via the network 1140. The processor 1120 is configured to execute the instructions 1161 encoded in the storage medium 1160 in order to cause the EDA system 1100 to be usable for performing a portion or all of the noted processes and/or methods. In one or more embodiments, the processor 1120 is a central processing unit (CPU), a multi-processor, a distributed processing system, an application specific integrated circuit (ASIC), and/or a suitable processing unit.

In one or more embodiments, the storage medium 1160 is an electronic, magnetic, optical, electromagnetic, infrared, and/or a semiconductor system (or apparatus or device). For example, the storage medium 1160 includes a semiconductor or solid-state memory, a magnetic tape, a removable computer diskette, a random access memory (RAM), a read-only memory (ROM), a rigid magnetic disk, and/or an optical disk. In one or more embodiments using optical disks, the storage medium 1160 includes a compact disk-read only memory (CD-ROM), a compact disk-read/write (CD-R/W), and/or a digital video disc (DVD).

In one or more embodiments, the storage medium 1160 stores the instructions 1161 configured to cause the EDA system 1100 (where such execution represents (at least in part) the EDA tool) to be usable for performing a portion or all of the noted processes and/or methods. In one or more embodiments, the storage medium 1160 also stores information which facilitates performing a portion or all of the noted processes and/or methods. In one or more embodiments, storage medium 1160 stores library 1162 of standard cells including such standard cells as disclosed herein, for example, bit cells disclosed in FIGS. 1-3, 4A-4B, 5A-5G, 6A-6B, 7A-7B, 8A-8B and 9A-9B.

The EDA system 1100 includes the I/O interface 1110. The I/O interface 1110 is coupled to external circuitry. In one or more embodiments, the I/O interface 1110 includes a keyboard, keypad, mouse, trackball, trackpad, touchscreen, and/or cursor direction keys for communicating information and commands to the processor 1120.

EDA system 1100 also includes the network interface 1130 coupled to processor 1120. The network interface 1130 allows the EDA system 1100 to communicate with the network 1140, to which one or more other computer systems are connected. The network interface 1130 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 also includes the fabrication tool 1170 coupled to the processor 1120. The fabrication tool 1170 is configured to fabricate integrated circuits, e.g., the integrated circuit in FIGS. 1 and 2, according to the design files processed by the processor 1120.

The EDA system 1100 is configured to receive information through I/O interface 1110. The information received through the I/O interface 1110 includes one or more of instructions, data, design rules, libraries of standard cells, and/or other parameters for processing by the processor 1120. The information is transferred to the processor 1120 via the bus 1150. The EDA system 1100 is configured to receive information related to a user interface (UI) through the I/O interface 1110. The information is stored in computer-readable storage medium 1160 as user interface (UI) 1163.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

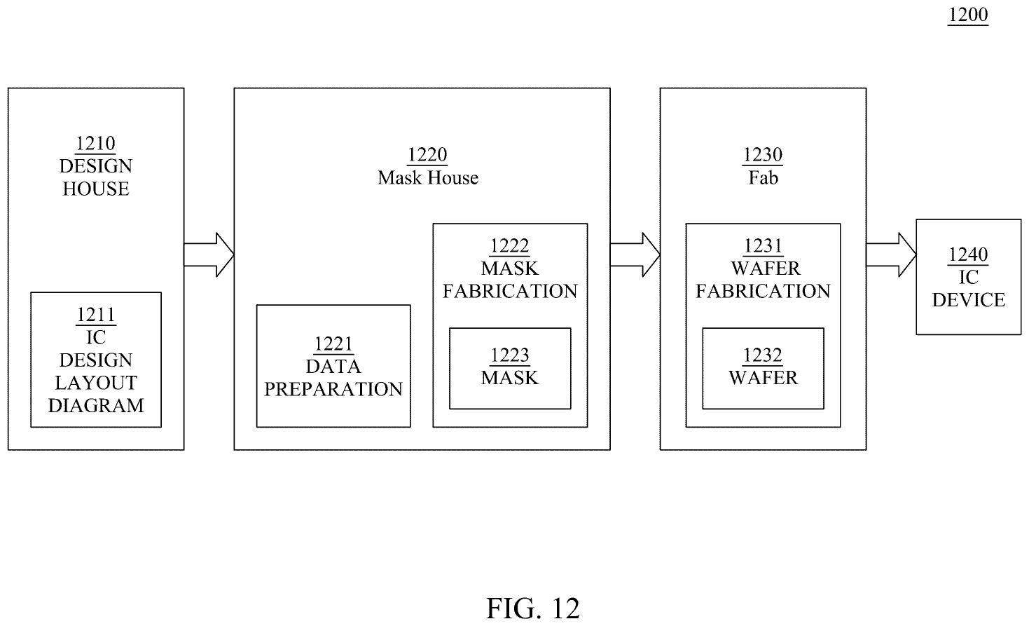

FIG. 12 is a block diagram of IC manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using the IC manufacturing system 1200.

In FIG. 12, the IC manufacturing system 1200 includes entities, such as a design house 1210, a mask house 1220, and an IC manufacturer/fabricator (“fab”) 1230, that interact with one another in the design, development, and manufacturing cycles and/or services related to manufacturing an IC device 1240. The entities in IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1210, mask house 1220, and IC fab 1230 is owned by a single larger company. In some embodiments, two or more of design house 1210, mask house 1220, and IC fab 1230 coexist in a common facility and use common resources.

Design house (or design team) 1210 generates an IC design layout diagram 1211. The IC design layout diagram 1211 includes various geometrical patterns, for example, an IC layout design depicted in FIGS. 4A-4B, 5A-5G, 6A-6B, 7A-7B, 8A-8B and 9A-9B. The geometrical patterns correspond to patterns of metal, oxide, or semiconductor layers that make up the various components of IC device 1240 to be fabricated. The various layers combine to form various IC features. For example, a portion of IC design layout diagram 1211 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1210 implements a proper design procedure to form IC design layout diagram 1211. The design procedure includes one or more of logic design, physical design or place and route. The IC design layout diagram 1211 is presented in one or more data files having information of the geometrical patterns. For example, the IC design layout diagram 1211 can be expressed in a GDSII file format or DFII file format.

The mask house 1220 includes data preparation 1221 and mask fabrication 1222. The mask house 1220 uses the IC design layout diagram 1211 to manufacture one or more masks 1223 to be used for fabricating the various layers of IC device 1240 according to the IC design layout diagram 1211. The mask house 1220 performs mask data preparation 1221, where IC design layout diagram 1211 is translated into a representative data file (“RDF”). The mask data preparation 1221 provides the RDF to the mask fabrication 1222. The mask fabrication 1222 includes a mask writer. A mask writer converts the RDF to an image on a substrate, such as a mask (reticle) 1223 or a semiconductor wafer 1232. The IC design layout diagram 1211 is manipulated by the mask data preparation 1221 to comply with particular characteristics of the mask writer and/or requirements of the IC fab 1230. In FIG. 12, the data preparation 1221 and the mask fabrication 1222 are illustrated as separate elements. In some embodiments, the data preparation 1221 and the mask fabrication 1222 can be collectively referred to as mask data preparation.

In some embodiments, the data preparation 1221 includes optical proximity correction (OPC) which uses lithography enhancement techniques to compensate for image errors, such as those that can arise from diffraction, interference, other process effects and the like. The OPC adjusts the IC design layout diagram 1211. In some embodiments, the data preparation 1221 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats the OPC as an inverse imaging problem.

In some embodiments, data preparation 1221 includes a mask rule checker (MRC) that checks the IC design layout diagram 1211 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1211 to compensate for limitations during the mask fabrication 1222, which may undo part of the modifications performed by OPC in order to meet mask creation rules.

In some embodiments, data preparation 1221 includes lithography process checking (LPC) that simulates processing that will be implemented by the IC fab 1230 to fabricate the IC device 1240. The LPC simulates this processing based on IC design layout diagram 1211 to create a simulated manufactured device, such as IC device 1240. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by the LPC, if the simulated device is not close enough in shape to satisfy design rules, the OPC and/or the MRC are be repeated to further refine the IC design layout diagram 1211.

It should be understood that the above description of data preparation 1221 has been simplified for the purposes of clarity. In some embodiments, data preparation 1221 includes additional features such as a logic operation (LOP) to modify the IC design layout diagram 1211 according to manufacturing rules. Additionally, the processes applied to IC design layout diagram 1211 during data preparation 1221 may be executed in a variety of different orders.

After the data preparation 1221 and during mask fabrication 1222, a mask 1223 or a group of masks 1223 are fabricated based on the modified IC design layout diagram 1211. In some embodiments, the mask fabrication 1222 includes performing one or more lithographic exposures based on the IC design layout diagram 1211. In some embodiments, an electron-beam (e-beam) or a mechanism of multiple e-beams is used to form a pattern on a mask (photomask or reticle) 1223 based on the modified IC design layout diagram 1211. The mask 1223 can be formed in various technologies. In some embodiments, the mask 1223 is formed using binary technology. In some embodiments, a mask pattern includes opaque regions and transparent regions. A radiation beam, such as an ultraviolet (UV) beam, used to expose the image sensitive material layer (for example, photoresist) which has been coated on a wafer, is blocked by the opaque region and transmits through the transparent regions. In one example, a binary mask version of the mask 1223 includes a transparent substrate (for example, fused quartz) and an opaque material (for example, chromium) coated in the opaque regions of the binary mask. In another example, the mask 1223 is formed using a phase shift technology. In a phase shift mask (PSM) version of the mask 1223, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1222 is used in a variety of processes. For example, such a mask(s) is used in an ion implantation process to form various doped regions in the semiconductor wafer 1232, in an etching process to form various etching regions in the semiconductor wafer 1232, and/or in other suitable processes.

The IC fab 1230 includes wafer fabrication 1231. The IC fab 1230 is an IC fabrication business that includes one or more manufacturing facilities for the fabrication of a variety of different IC products. In some embodiments, the IC Fab 1230 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1230 uses mask(s) 1223 fabricated by mask house 1220 to fabricate the IC device 1240. Thus, the IC fab 1230 at least indirectly uses IC design layout diagram 1211 to fabricate the IC device 1240. In some embodiments, the semiconductor wafer 1233 is fabricated by the IC fab 1230 using the mask(s) 1223 to form IC device 1240. In some embodiments, the IC fabrication includes performing one or more lithographic exposures based at least indirectly on the IC design layout diagram 1211. Semiconductor wafer 1233 includes a silicon substrate or other proper substrate having material layers formed thereon. The semiconductor wafer 1233 further includes one or more of various doped regions, dielectric features, multilevel interconnects, and the like (formed at subsequent manufacturing steps).

As described above, embodiments of the present disclosure provide a semiconductor device and a method to manufacture the semiconductor device. The semiconductor device has optimized cell scaling capability and metal conductor RC reduction with the double side (front side and backside) layout. The backside of the semiconductor device serves for conductors (metal lines, vias, etc.) of the supply voltages VSS and/or VDD. The bump pads and bumping are arranged at the backside. Therefore, the power conductors are directly connected to power bumps (or having shorter path) and IR drop is reduced. In some embodiments, the metal one layer is only served for write bit lines and read bit lines. Metal line width for write and read bit lines can be wider to reduce bit line RC delay. This benefits to bit cell speed and helps lower the minimum write voltage level. The metal layer M2 and above metal layers are purely served for write and read word lines and there help reduce RC delay of the word lines.

In some embodiments, a semiconductor device is provided. The semiconductor device comprises a bit cell comprising first and second inverters and a first transistor. The first inverter comprising a second transistor and a third transistor that share a first gate structure extending along a first direction. The second transistor is coupled to a first metal line in a backside of the semiconductor device to receive a first supply voltage. The second inverter is cross-coupled with the first inverter and comprises a fourth transistor and a fifth transistor that share a second gate structure extending along the first direction. The first transistor and second transistors share a first active area extending along a second direction. The first transistor receives first data from a first bit line in a front side of the semiconductor device.

In some embodiments, a semiconductor device is provided. The semiconductor device comprises a bit cell comprising first to third gate structures and first to fifth active regions. The first gate structure extends along a first direction. The second gate structure extends along the first direction and separated from the first gate structure along a second direction. The first active region is between the first and second gate structures. The first active region corresponds to a first terminal of a first transistor and the first gate structure corresponds to a gate terminal of the first transistor. The second active region is between the first and second gate structures. The second active region corresponds to a first terminal of a second transistor and the second gate structure corresponds to a gate terminal of the second transistor. The third active region is between the first and third gate structures. The third active region corresponds to a first terminal of a third transistor and the first gate structure further corresponds to a gate terminal of the third transistor. The third active region further corresponds to a first terminal of a fourth transistor and the third gate structure corresponds to a gate terminal of the fourth transistor. The fourth active region is coupled to a first metal line that transmits a first supply voltage in a backside of the semiconductor device. The fourth active region corresponds to a second terminal of the third transistor. The fifth active region is coupled to a write bit line in a front side of the semiconductor device. The fifth active region corresponds to a second terminal of the fourth transistor.

In some embodiments, a method for manufacturing a semiconductor device is provided. The method comprises: forming a first active area and a second active area that extend along a first direction and have a first width; forming a third active area and a fourth active area that extend along the first direction and have a second width smaller than the first width; forming a first gate structure that extends along a second direction and crosses the first and third active areas in a top view, wherein the first gate structure, the first active area and the third active area correspond to a first inverter of a bit cell; forming a second gate structure crossing the second and fourth active areas in the top view, wherein the second gate structure, the second active area and the fourth active area correspond to a second inverter of the bit cell; forming a third gate structure crossing the first active area; forming a first contact that connects a first portion of the first active area and the third active area, wherein the first portion of the first active area is between the first and third gate structures and is at a first side of the third gate structure and a first side of the first gate structure; forming a write bit line in a front side of the semiconductor device, wherein the write bit line is coupled to a second portion of the first active area at a second side of the third gate structure; and forming a first power rail crossing the first and second gate structures in a backside of the semiconductor device, wherein the first power rail is coupled to a third portion of the first active area at a second side of the first gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first inverter comprising a first transistor and a second transistor that share a first gate structure extending along a first direction,
wherein the first transistor is coupled to a first metal line in a backside of the semiconductor device to receive a first supply voltage;
a second inverter cross-coupled with the first inverter and comprising a third transistor and a fourth transistor that share a second gate structure extending along the first direction; and
a fifth transistor, wherein the first and fifth transistors share a first active area extending along a second direction,
wherein the fifth transistor is configured to receive first data from a first bit line in a front side of the semiconductor device.

2. The semiconductor device of claim 1, wherein the fifth transistor comprises a third gate structure extending along the first direction,
wherein the third gate structure is coupled to a write word line extending along the first direction.

3. The semiconductor device of claim 2, further comprising:
a sixth transistor comprising a fourth gate structure that is coupled to the write word line,
wherein the sixth transistor is configured to transmit second data to the third transistor through a second active area extending along the second direction.

4. The semiconductor device of claim 2, wherein the second and fourth transistors share a second active area,
wherein a portion, between the first and third gate structures, of the first active area is coupled to a portion, between the first and second gate structures, of the second active area coupled to the second and fourth transistors.

5. The semiconductor device of claim 4, wherein a first width of the first active area is greater than a second width of the second active area along the first direction.

6. The semiconductor device of claim 1, further comprising:
a sixth transistor, wherein the third and sixth transistors share a second active area extending along the second direction,
wherein the sixth transistor is coupled to a second bit line in the front side of the semiconductor device,
wherein the second bit line is complementary to the first bit line.

7. The semiconductor device of claim 1, further comprising:
a sixth transistor sharing the second gate structure with the third and fourth transistors; and
a seventh transistor, wherein the sixth and seventh transistors share a second active area extending along the second direction,
wherein the seventh transistor comprises a third gate structure that is coupled to a read word line extending along the first direction.

8. The semiconductor device of claim 7, wherein the sixth transistor is coupled to a second metal line in the backside,
wherein the second metal line is configured to transmit the first supply voltage.

9. The semiconductor device of claim 1, wherein the second and fourth transistors are coupled to a second metal line in the backside,
wherein the second metal line is configured to transmit a second supply voltage higher than the first supply voltage.

10. A semiconductor device, comprising:
a first gate structure extending along a first direction;
a second gate structure extending along the first direction and separated from the first gate structure along a second direction;
a first active region between the first and second gate structures, wherein the first active region corresponds to a first terminal of a first transistor and the first gate structure corresponds to a gate terminal of the first transistor;
a second active region between the first and second gate structures, wherein the second active region corresponds to a first terminal of a second transistor and the second gate structure corresponds to a gate terminal of the second transistor;
a third gate structure;
a third active region between the first and third gate structures, wherein the third active region corresponds to a first terminal of a third transistor and the first gate structure further corresponds to a gate terminal of the third transistor,
wherein the third active region further corresponds to a first terminal of a fourth transistor and the third gate structure corresponds to a gate terminal of the fourth transistor;
a fourth active region coupled to a first metal line that transmits a first supply voltage in a backside of the semiconductor device, wherein the fourth active region corresponds to a second terminal of the third transistor; and
a fifth active region coupled to a write bit line in a front side of the semiconductor device, wherein the fifth active region corresponds to a second terminal of the fourth transistor.

11. The semiconductor device of claim 10, wherein the third gate structure is coupled to a write word line in the front side.

12. The semiconductor device of claim 11, further comprising:
a fourth gate structure coupled to the write word line; and
a sixth active region between the second and fourth gate structures, wherein the sixth active region corresponds to a first terminal of a fifth transistor and the fourth gate structure corresponds to a gate terminal of fifth transistor.

13. The semiconductor device of claim 10, further comprising:
a sixth active region aligned with the first active region along the second direction, wherein the sixth active region corresponds to a second terminal of the first transistor,
wherein the sixth active region is coupled to a second metal line transmitting a second supply voltage in the front side.

14. The semiconductor device of claim 10, further comprising:
a fourth gate structure corresponding to a gate structure of a fifth transistor, wherein the fourth gate structure is coupled to a read word line in the front side;
a sixth active region between the second and fourth gate structure, wherein the sixth active region corresponds to a first terminal of the fifth transistor; and
a seventh active region corresponding to a second terminal of the fifth transistor, wherein the seventh active region is coupled to a read bit line in the front side.

15. The semiconductor device of claim 14, further comprising:
an eighth active region aligned with the sixth active region along the second direction, wherein the eight active region corresponds to a first terminal of a sixth transistor and the second gate structure corresponds to a gate terminal of the sixth transistor,
wherein the eighth active region is coupled to a second metal line transmitting the first supply voltage in the backside,
wherein a third metal line is coupled between the first and second metal lines,
wherein the third metal line is under the first and second metal lines and extends along the first direction.

16. A method of manufacturing a semiconductor device, comprising:
forming a first active area and a second active area that extend along a first direction and have a first width;
forming a third active area and a fourth active area that extend along the first direction and have a second width smaller than the first width;
forming a first gate structure that extends along a second direction and crosses the first and third active areas in a top view, wherein the first gate structure, the first active area and the third active area correspond to a first inverter of a bit cell;
forming a second gate structure crossing the second and fourth active areas in the top view, wherein the second gate structure, the second active area and the fourth active area correspond to a second inverter of the bit cell;
forming a third gate structure crossing the first active area;
forming a first contact that connects a first portion of the first active area and the third active area, wherein the first portion of the first active area is between the first and third gate structures and is at a first side of the third gate structure and a first side of the first gate structure;
forming a write bit line in a front side of the semiconductor device, wherein the write bit line is coupled to a second portion of the first active area at a second side of the third gate structure; and
forming a first power rail crossing the first and second gate structures in a backside of the semiconductor device, wherein the first power rail is coupled to a third portion of the first active area at a second side of the first gate structure.

17. The method of claim 16, further comprising:
forming a write word line extending along the second direction, wherein the write word line is coupled to the third gate structure.

18. The method of claim 17, further comprising:
forming a fourth gate structure crossing the second active area;
forming a second contact that connects a first portion of the second active area and the fourth active area, wherein the first portion of the second active area is between the second and fourth gate structures and is at a first side of the second gate structure and a first side of the fourth gate structure; and
forming a complementary write bit line in the front side, wherein the complementary write bit line is coupled to a second portion of the second active area at a second side of the fourth gate structure.

19. The method of claim 16, further comprising:
forming a fifth active area extending along the first direction, wherein the second gate structure extends across the fifth active area;
forming a fourth gate structure crossing the fifth active area; and
forming a read word line coupled to the fourth gate structure.

20. The method of claim 19, further comprising:
forming a read bit line coupled to the fifth active area.
